(19) United States
(12) Patent Application Publication
(10) Pub. No.: US 2025/0168968 A1
(43) Pub. Date: May 22, 2025

(54) PRINTED DE-COUPLING PLANE FOR PRINTED CIRCUIT BOARDS

(71) Applicant: Microsoft Technology Licensing, LLC, Redmond, WA (US)

(72) Inventors: Chee Kiong FONG, Saratoga, CA (US); Ying LIANG, Shenzhen (CN); Geoffrey Jason SHEW, Redmond, WA (US); Michael Roy VOLKMAN, Port Townsend, WA (US); Suet Fong TIN, Redmond, WA (US); Marshall Thomas DEPUE, Redmond, WA (US)

(21) Appl. No.: 18/835,151

(22) PCT Filed: Feb. 3, 2022
(86) PCT No.: PCT/CN2022/075316

§ 371 Date: Aug. 1, 2024

(51) Int. Cl. H05K 1/02; H05K 1/09; H05K 1/18; H05K 3/46

(52) U.S. Cl. CPC H05K 1/0216; H05K 1/092; H05K 1/181; H05K 3/4644

(57) ABSTRACT

Printed circuit boards (PCBs) are a fundamental component used in nearly all electronics. PCBs provide electrical connections and mechanical support to electronic components and are generally made of copper layers laminated onto, though, and/or between one or more non-conductive substrate layers. Depending on the circuit complexity and performance requirements, multiple copper layers may be utilized in a singular PCB. Beyond two copper layers, the material cost and environmental impact of adding additional copper layers to a PCB increases dramatically. Multiple internal conductive layers (e.g., copper clad laminates or CCL's) within a PCB are created using an energy intensive process, requiring substantial amounts of water and chemicals. Significant environmental savings and PCB manufacturing cost reductions can be achieved if a PCB design can minimize the number of internal conductive layers, including using one or more printed de-coupling layers in place of laminated copper layers.

### BACKGROUND

A printed circuit board (PCB) mechanically supports and electrically interconnects an array of electronic components using conductive traces, vias, and other features etched from metallic sheets laminated onto a non-conductive substrate. Typically, the PCB includes at least one internal copper layer for noise de-coupling, as well as at least a second copper layer that is used to form the conductive traces, vias, and other features.

### SUMMARY

Implementations described and claimed herein provide a printed circuit board comprising: a substrate forming a mechanical base for the printed circuit board; a first copper layer laminated to a first side of the substrate forming a first conductive metallic paths for the printed circuit board; a first solder mask applied over the first copper layer and the first side of the substrate to seal the first array of conductive metallic paths from an external environment; and a first de-coupling plane printed on the printed circuit board using conductive ink.

Implementations described and claimed herein further provide a method of manufacturing a printed circuit board, the method comprising: providing a substrate forming a mechanical base for the printed circuit board; laminating a first copper layer to a first side of the substrate forming a first array of conductive metallic paths for the printed circuit board; applying a first solder mask over the first copper layer and the first side of the substrate to seal the first array of conductive metallic paths from an external environment; and printing a first de-coupling plane on the printed circuit board using conductive ink.

Other implementations are also described and recited herein. This Summary is provided to introduce a selection of concepts in a simplified form that are further described below in the Detailed Descriptions. This Summary is not intended to identify key features or essential features of the claimed subject matter, nor is it intended to be used to limit the scope of the claimed subject matter.

### BRIEF DESCRIPTIONS OF THE DRAWINGS

FIG. 1 illustrates section view of an example printed circuit board (PCB) including a printed de-coupling plane.

FIG. 2 illustrates a conventional PCB stack-up as compared to an example PCB stack-up including printed de-coupling planes.

FIG. 3 illustrates another example PCB stack-up including a singular printed de-coupling plane.

FIG. 4 illustrates a comparison of radiated emissions from a conventional PCB stack-up as compared to an example PCB stack-up including a printed de-coupling plane.

FIG. 5 illustrates a comparison of common mode noise emitted from a conventional PCB stack-up as compared to an example PCB stack-up including a printed de-coupling plane.

FIG. 6 illustrates example operations for manufacturing an example PCB including a printed de-coupling plane.

FIG. 7 illustrates other example operations for manufacturing an example PCB including a printed de-coupling plane.

### DETAILED DESCRIPTIONS

Printed circuit boards (PCBs) are a fundamental component used in nearly all electronics. PCBs provide electrical connections and mechanical support to electronic components and are generally made of copper layers laminated onto, though, and/or between one or more non-conductive substrate layers. The copper layers are etched with traces, planes and other features to create electrical connections for the electronic components. Vias are formed through the non-conductive substrate layers to connect electronic components on opposing sides of the substrate layer(s).

Depending on the circuit complexity and performance requirements, multiple copper layers may be utilized in a singular PCB. For example, a second copper layer is often used to provide an electrical ground and/or de-coupling plane to meet noise and electromagnetic compatibility (EMC) requirements. Beyond two copper layers, the material cost and environmental impact of adding additional copper layers to a PCB increases dramatically. This is because internal conductive layers (e.g., copper clad laminates or CCL's) are created using a time and energy intensive process, requiring significant amounts of water and chemicals. Significant environmental savings and PCB manufacturing cost reductions can be achieved if a PCB design can minimize the number of internal conductive layers, including using one or more printed de-coupling layers in place of laminated copper layers.

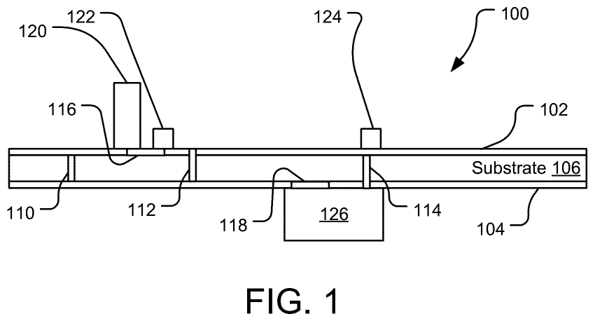

FIG. 1 illustrates section view of an example printed circuit board (PCB) 100 including printed de-coupling planes 102, 104. The PCB 100 includes an insulating substrate 106 (e.g., a woven fiberglass cloth with an epoxy resin binder) with a network of conductive vias (e.g., vias 110, 112, 114), traces (e.g., traces 116, 118) and other conductive paths or areas thereon. The PCB 100 further includes a variety of electronic components (e.g., electronic components 120, 122, 124) soldered to the network of conductive paths on a first side of the substrate 106 and other electronic components (e.g., electronic component 126) soldered to the network of conductive paths on a second side of the substrate 106 to create a functional electrical network interconnecting the electronic components on both sides of the substrate 106, as well as through the substrate 106.

In various implementations, the electronic components 120, 122, 124, 126 or other electronic components (not shown) may include capacitors, resistors, microprocessors, storage devices, etc. The PCB 100 may be single-sided (e.g., having one layer forming the conductive network), double-sided (e.g., having two conductive layers forming the conductive network, as shown in FIG. 1) or multi-layer (e.g., having inner and outer conductive layers forming the conductive network). Various implementations described herein may be implemented on single-sided, double-sided, or multi-layer PCBs.

Conductive paths on different sides of the substrate 106 may be connected with vias. In various implementations, a far greater number and complexity of conductive traces, vias, and other paths, as well as electronic components, are included in the PCB 100 as compared to that shown in FIG. 1. Further, PCBs as referred to herein are defined as any insulating substrate with a network of conductive paths formed thereon or therein. In various implementations, the substrate 106 may include ceramics, fiberglass, plastics (e.g., flexible polymers), or any combination thereof. In one example implementation, the PCB 100 is a flexible printed circuit (“FPC”) on a polyimide substrate. The conductive paths or areas are generally made of copper alloys (also referred to as simply copper herein).

Due to the close proximity of the electronic components 120, 122, 124, 126 within the PCB 100, inductance caused by one of the electronic components and/or its associated conductive network may cause unacceptable noise and/or interference. Traditionally, a second copper layer is used to provide a de-coupling plane to provide a return path for high-frequency current generated by any of the electronic components 120, 122, 124, 126 back to its source. The high-frequency current would otherwise radiate outward from the electronic component as electromagnetic noise and potentially interfere with the operation of the other(s) of the electronic components 120, 122, 124, 126. However, as noted above, additional copper layers add substantial cost and environmental impact in manufacturing.

Conductive ink is printable and suitable to print one or more external noise de-coupling layers on a PCB, such as PCB 100. In various implementations, the conductive ink may include carbon, copper, silver, or other conductive materials in a powdered form suspended within a printable solution. As copper, silver, and other metals are readily conductive, their use to make the printed de-coupling planes 102, 104 allows the printed de-coupling planes 102, 104 to serve as both a high-frequency current return path and a common electrical ground for low-frequency current. Despite being higher impedance than copper and silver, for example, conductive ink using powdered carbon is still effective for creating de-coupling planes to serve as a high-frequency current return path to isolate noise and provide de-coupling between electronic components. A common electrical ground for low-frequency current may be otherwise provided for in the copper conductive network (e.g., traces and vias). Copper structures and layers as used herein to form the conductive network (e.g., traces and vias) includes alloys that include copper as their principal component. Copper, silver, or other metal powders used in the conductive ink as used herein includes powdered alloys that include copper, silver, or another conductive metals as a principal component.

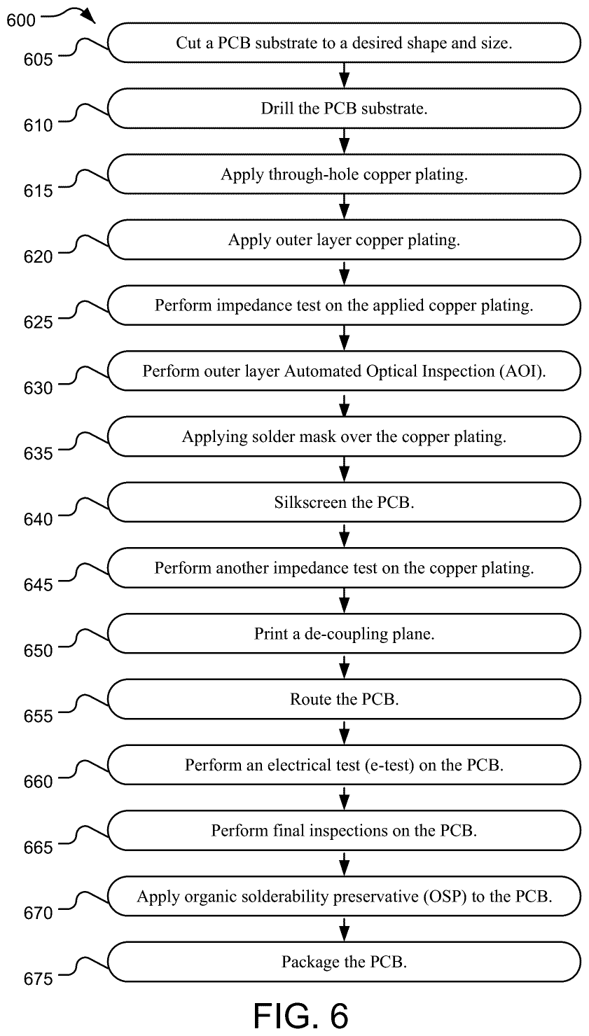

Instead of using internal copper layers to provide noise de-coupling planes, printed de-coupling planes 102, 104 are printed on top and bottom of the PCB 100 to achieve similar or better performance as compared to a laminated copper de-coupling plane, which reduces overall copper layer count within the PCB 100. Both environmental and cost savings are achieved with printed de-coupling planes 102, 104 by less energy and materials required for printing conductive layers as compared to laminating copper layers as well as fewer manufacturing process steps (see e.g., FIG. 6 and detailed description below). This allows production of greener electronics using the printed de-coupling plane(s) at a lower cost than conventional laminated copper de-coupling plane(s).

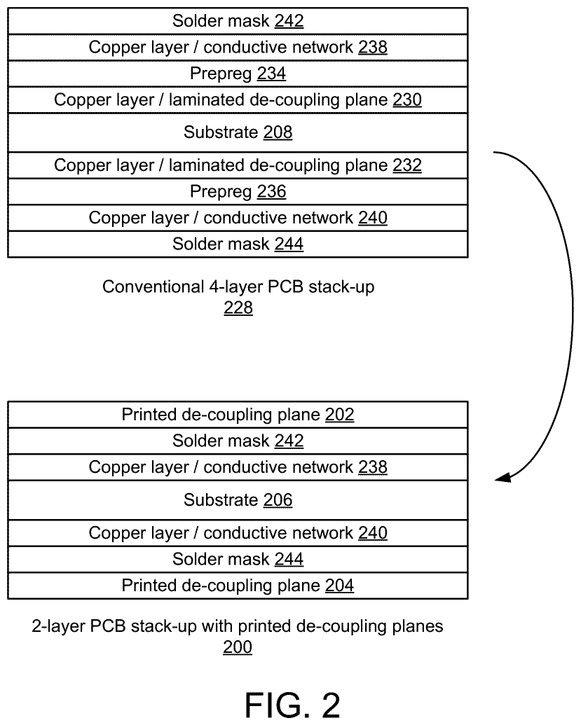

FIG. 2 illustrates a conventional PCB stack-up 228 as compared to an example PCB stack-up 200 including printed de-coupling planes 202, 204. Both of the PCB stack-ups 200, 228 are illustrated as utilizing both sides of a substrate 208. In other implementations, only one side of the substrate 208 is used to form the PCB stack-ups. Further, the conventional PCB stack-up 228 is illustrated as a 4-layer stack-up and the PCB stack-up 200 is illustrated as an equivalently functioning 2-layer stack-up. In other implementations, both the PCB stack-ups 200, 228 may have greater or fewer copper layers, however, PCB stack-ups made with any number of copper layers accordingly to the presently disclosed technology may function similarly to conventional PCB stack-ups that require additional copper layers for noise de-coupling purposes.

The conventional 4-layer PCB stack-up 228 includes a substrate 208, as described above with reference to substrate 106 of FIG. 1. Copper de-coupling planes 230, 232 are applied to each side of the substrate 208. Prepreg layers 234, 236 (e.g., a dielectric adhesive) are applied over each of the copper de-coupling planes 230, 232 to electrically isolate the copper de-coupling planes 230, 232 from copper conductive network planes 238, 240, which are applied over the prepreg layers 234, 236. The prepreg layers 234, 236 further serve to adhere the copper de-coupling planes 230, 232 to the copper conductive network planes 238, 240, respectively. Solder mask layers 242, 244 (e.g., a thin polymer) are applied over the copper conductive network planes 238, 240 to protect the copper conductive network and underlying exposed areas from damage from an external environment (e.g., corrosion, mechanical impact damage, etc.), as well as provide additional isolation between features of the copper conductive network.

The 2-layer PCB stack-up 200 according to the presently disclosed technology includes a substrate 206 similar to substrate 208, also as described above with reference to substrate 106 of FIG. 1. Copper layers 238, 240 are laminated to each side of the substrate 206 and subsequently etched and/or plated to form the conductive network. Solder mask layers 242, 244 (e.g., a thin polymer) are applied over the copper conductive network planes 238, 240 to protect the copper conductive network and underlying exposed areas from damage from an external environment (e.g., corrosion, mechanical impact damage, etc.), as well as provide additional isolation between features of the conductive network.

Portions of the corresponding to electrical ground, soldering pads, and other copper features that are intended to remain exposed may be masked such that the solder mask is excluded from those areas. The printed de-coupling planes 202, 204 are printed over the solder mask layers 242, 244 and serve a similar purpose as the laminated copper de-coupling planes 230, 232 of the conventional 4-layer PCB stack-up 228. The printed de-coupling planes 202, 204 may make connection with electrical ground within the conductive network by virtue of the lack of solder mask in the excluded areas. This electrically links the printed de-coupling planes 202, 204 to ground within the conductive network, which may improve the de-coupling function of the printed de-coupling planes 202, 204 and/or permit the printed de-coupling planes 202, 204 to function as alternative paths to ground. More specifically, the printed de-coupling planes 202, 204 may serve as at least high-frequency current return paths and further as common electrical ground for low-frequency current, if the printed de-coupling planes 202, 204 are sufficiently conductive.

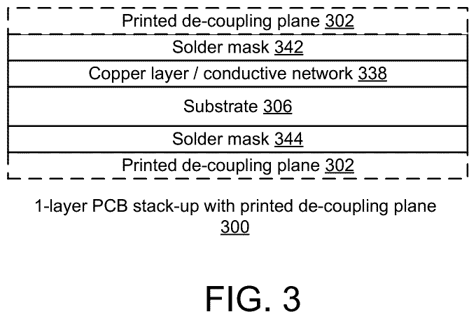

FIG. 3 illustrates another example PCB stack-up 300 including a singular printed de-coupling plane 302. As compared to the PCB stack-up 200 of FIG. 2, the PCB stack-up 300 utilizes only one side of a substrate 306 for a copper layer 338 forming a conductive network. Therefore, the PCB stack-up 300 may be referred to as a 1-layer stack-up, which may be considered equivalent in function to a conventional 2-layer stack-up.

The 1-layer PCB stack-up 300 according to the presently disclosed technology includes a substrate 306, as described above with reference to substrate 106 of FIG. 1. A copper layer 338 is laminated to one side of the substrate 306 and subsequently etched and plated to form the conductive network. A solder mask layers 342 (e.g., a thin polymer) is applied over the copper conductive network planes 338 to protect the copper conductive network and underlying exposed areas from damage from an external environment (e.g., corrosion, mechanical impact damage, etc.), as well as provide additional isolation between features of the conductive network.

A conductive de-coupling plane 302 is printed on either side (or both sides) of the substrate 306, as illustrated by dashed boxes indicating de-coupling plane 302 in two possible locations. Regardless of location, the conductive de-coupling plane 302 serves a similar purpose as a laminated copper de-coupling plane of a conventional 2-layer PCB stack-up. When printed above the substrate 306, the conductive de-coupling plane 302 is printed over the solder mask 342 and solder mask 344 may be omitted. When printed below the substrate 306, a solder mask layer 344 may be first applied over the substrate 306, followed by the conductive de-coupling plane 302.

In some implementations, the printed de-coupling plane 302 may make connection with electrical ground within the conductive network by using vias through the substrate 306. The printed de-coupling plane 302 may serve as at least a high-frequency current return path and further as common electrical ground for low-frequency current, if the printed de-coupling plane 302 is sufficiently conductive. In some implementations, a further solder mask layer may be applied over the printed de-coupling plane 302 to protect the de-coupling plane 302 from damage from an external environment (e.g., corrosion, mechanical impact damage, etc.).

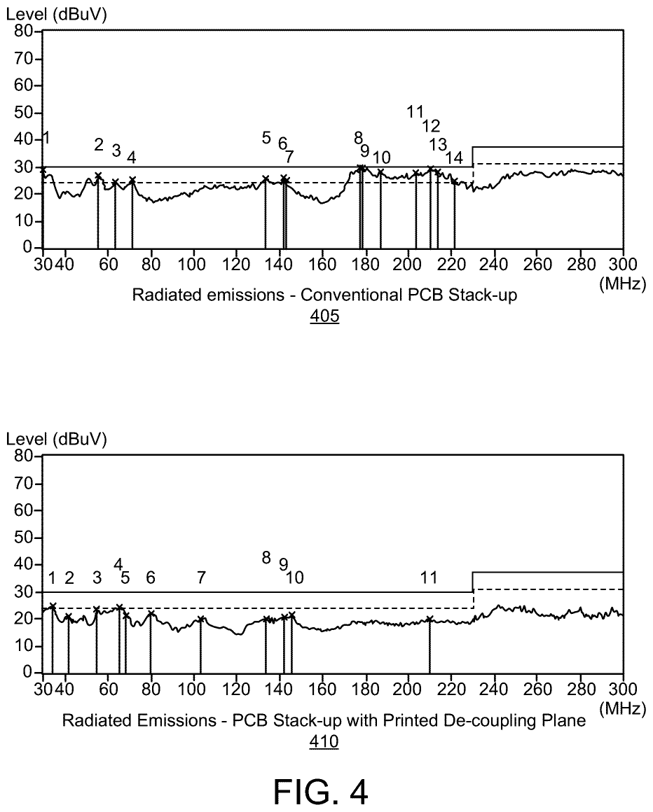

FIG. 4 illustrates a comparison of radiated emissions from a conventional PCB stack-up 405 as compared to radiated emissions from an example PCB stack-up including a printed de-coupling plane 410. Radiated emissions from a conventional PCB stack-up peaks at approximately 30 bBuV at approximately 180 MHz and 210 MHz (positions 8, 9, and 12). This is compared to radiated emissions from an example PCB stack-up including a printed de-coupling plane that peaks at approximately 25 bBuV at approximately 35 MHz and 60 MHz (positions 1, 3, and 4), an approximately 17% reduction in radiated emissions.

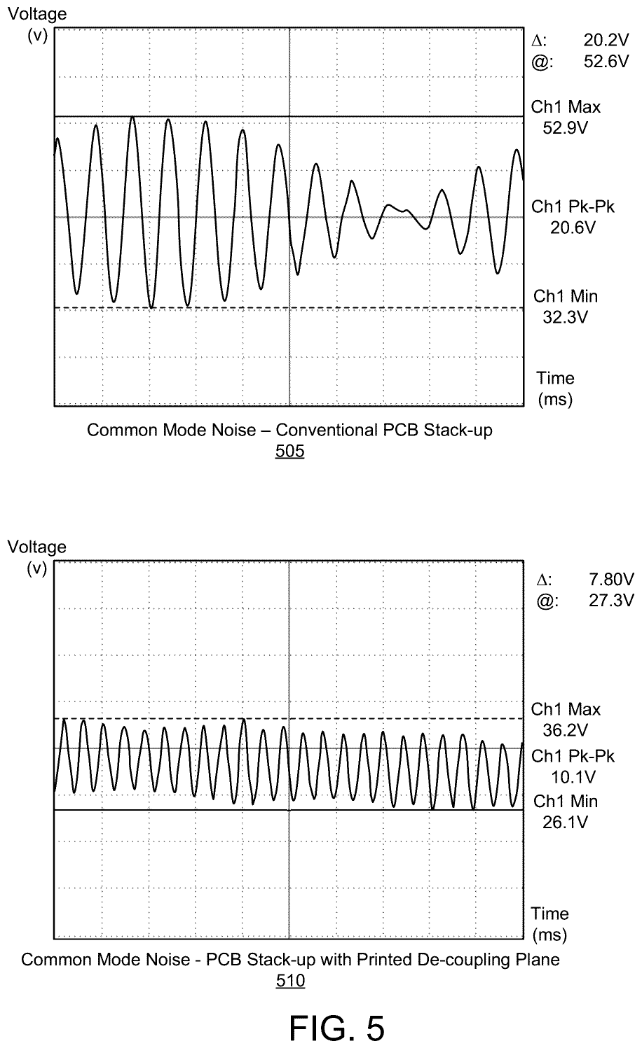

FIG. 5 illustrates a comparison of common mode noise emitted from a conventional PCB stack-up 505 as compared to common mode noise emitted from an example PCB stack-up including a printed de-coupling plane 510. Common mode noise emitted from a conventional PCB stack-up peaks at approximately 20.2V. This is compared to common mode noise emitted from an example PCB stack-up including a printed de-coupling plane that peaks at approximately 7.8V, an approximately 61% reduction in peak-to-peak noise.

FIG. 6 illustrates example operations 600 for manufacturing an example PCB including a printed de-coupling plane. Multilayer PCBs require significant energy and resources to produce. Typically processing requires numerous steps of cleaning, surface preparation, plating, and etching. These activities require large amounts of clean water, chemical solutions, and energy. The spent chemicals such as acid solutions, solvents and wastewater are detrimental to the environment. If some of the traditional laminated/etched/and plated copper layers are replaced with printable conductive layers on the top and/or bottom of the PCB, the PCB may be manufactured using fewer raw materials and with less energy consumption, in a shorter time period, and yielding an improved environmental impact from reduced wastewater and chemical byproducts. Operations 600 start with a material cutting operation 605, which cuts a PCB substrate to a desired shape and size.

In a method for manufacturing a conventional printed circuit board stack-up, a sequence of numerous steps are next used to place a laminated copper de-coupling plane onto the PCB substrate (e.g., degreasing, micro-etching, applying wet film, exposure, developing, application of fresh solution, precision etching, concentrated rinsing, striping, application of fresh solution, waste water rinsing, inner layer Automated Optical Inspection (AOI), punching, alkali rinse, pre-dip, oxide replacement, cooling, laminating, and cutting & grinding, with numerous acid rinsing, cascade water rinsing and drying steps between). These operations are generally replaced with a singular operation, printing a de-coupling plane 650, which is performed later in the method 600 as compared to a method for manufacturing a conventional printed circuit board stack-up.

Operations 600 continue with drilling the PCB substrate for mechanical attachments and vias 610, applying copper plating through hole (PTH) 615, applying outer layer copper plating 620, performing an impedance test on the copper plating 625, performing an outer layer Automated Optical Inspection (AOI) 630, applying a solder mask over the copper plating 635, silk screening the PCB 640, and performing another impedance test on the copper plating 645. Next, the singular step of printing a de-coupling plane 650 (e.g., printing carbon (or otherwise conductive) ink) is performed in place of the numerous steps referenced above in a conventional method for placing a laminated copper de-coupling plane onto the PCB substrate. The conductive ink printing process is simpler and greener than placing a laminated copper de-coupling plane, as discussed above. Operations 600 finish with routing the PCB 655, performing an electrical test (e-test) on the PCB 660, performing final inspections (FQA, FQC) on the PCB 665, applying organic solderability preservative (OSP) to the PCB 670, and packaging the PCB 675.

In various implementations, the total cost, water consumption, electricity, and time saved in performing method 600 to manufacture a 2-layer PCB (with printed de-coupling planes) as compared to performing a conventional method in manufacturing a 4-layer PCB (with laminated copper de-coupling planes) may be approximately 35-45%, 85-95%, 10-20%, 75-85%, respectively. Further, for manufacturing a 1.60 mm thick mid-Tg PCB, the total cost for manufacturing a 2-layer PCB (with printed de-coupling planes) as compared to manufacturing a 4-layer PCB (with laminated copper de-coupling planes) may be approximately 70-90%. Still further, manufacturing a 2-layer PCB (with printed de-coupling planes) may require 92% less water and 14.8% less electricity than a 4-layer PCB (with laminated copper de-coupling planes).

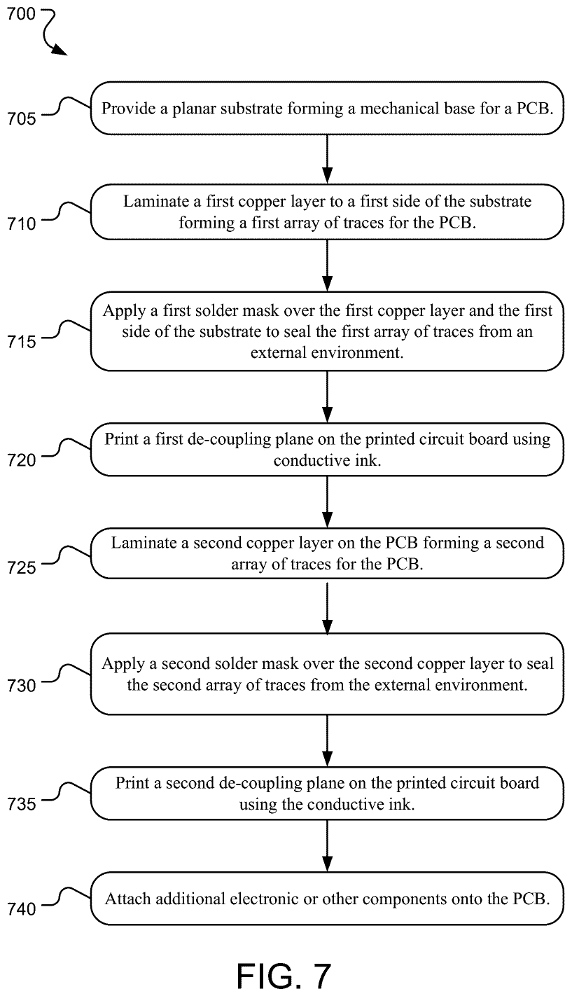

FIG. 7 illustrates further example operations 700 for manufacturing an example PCB including a printed de-coupling plane. A providing operation 705 provides a planar substrate forming a mechanical base for the PCB. In various implementations the PCB substrate includes ceramics, fiberglass, plastics, or any combination thereof. Further, the PCB substrate may be an FR-1 through FR-6 material, a G-10 or G-11 material, a CEM-1 through CEM-5 material, PTFE, PTFE composite, RF-35, aluminum or other metal core board (i.e., insulated metal substrate), alumina, polyimide foil, and polyimide-fluoropolymer composite foil.

A first laminating operation 710 laminates a first copper layer to a first side of the substrate forming a first array of traces (or conductive metallic paths) for the PCB. The laminated first copper layer forms one or more conductive metallic paths and/or pads on the PCB substrate. A first applying operation 715 applies a first solder mask over the first copper layer and the first side of the substrate to seal the first array of traces from an external environment. The first solder mask prevents the first array of traces (or copper conductive network) and underlying exposed areas from damage from an external environment (e.g., corrosion, mechanical impact damage, etc.), as well as provide additional isolation between features of the first array of traces. A first printing operation 720 prints a first de-coupling plane on the printed circuit board using conductive ink. The first de-coupling plane serves to as a high-frequency current return path and/or a common electrical ground for low-frequency current.

A second laminating operation 725 laminates a second copper layer on the PCB forming a second array of traces (or conductive metallic paths) for the PCB. The laminated second copper layer forms one or more conductive metallic paths and/or pads on the PCB substrate. In various implementations, the second copper layer may be laminated to a second side of the substrate or over the first de-coupling plane. The laminating operations 710, 725 are generally sets of subtractive, additive, and/or semi-additive processes. In a subtractive process, the PCB substrate starts with one or both planar surfaces entirely coated with metal (e.g., copper). Areas of the metal are removed from the PCB substrate leaving a network of conductive paths and pads remaining. In an additive process, the network of conductive paths and pads is electroplated onto an uncoated PCB substrate. In a semi-additive process, the PCB substrate contains a thin coating of metal on one or both of the planar surfaces of the PCB. A reverse mask is applied to the PCB substrate where additional metal plating is added to unmasked areas of the PCB. The mask is stripped away and any remaining thin areas of copper are stripped away, resulting in the network of conductive paths and pads remaining.

A second applying operation 730 applies a second solder mask over the second copper layer to seal the second array of traces from the external environment. In various implementations, the second solder mask is applied to either or both sides of the substrate and/or over the first or second printed de-coupling planes. The second solder mask prevents the first array of traces (or copper conductive network) and underlying exposed areas from damage from an external environment (e.g., corrosion, mechanical impact damage, etc.), as well as providing additional isolation between features of the first array of traces.

A second printing operation 735 prints a second de-coupling plane on the printed circuit board using the conductive ink. In various implementations, the second de-coupling plane is printed on either or both sides of the substrate and/or over the first or second solder masks. The conductive ink used for printing operations 720, 735 may include one or more of carbon, copper, and silver powder suspended within a printable solution. The second de-coupling plane also serves as a high-frequency current return path and/or a common electrical ground for low-frequency current. In some implementations, the first and/or second solder masks are excluded from one or more discrete areas of the first and/or second copper layers corresponding to electrical ground, soldering pads, and other copper features that are intended to remain exposed. The printed de-coupling planes may make connection with electrical ground within the conductive network by virtue of the lack of solder mask in the excluded areas.

A pick-and-place operation 740 attaches additional electronic or other components (e.g., resistors, capacitors, integrated circuits, and SOCs) onto the PCB. The additional electronic components or other components may be interference fit, soldered, adhered, and/or mechanically fastened, for example. The additional electronic or other components may be potential sources of noise that the first de-coupling plane serves to limit by providing the aforementioned high-frequency current return path and/or a common electrical ground for low-frequency current.

The operations making up the embodiments of the invention described herein are referred to variously as operations, steps, objects, or modules. The operations may be performed in any order, adding or omitting operations as desired, unless explicitly claimed otherwise or a specific order is inherently necessitated by the claim language.

Implementations disclosed and claimed herein include a printed circuit board comprising: a substrate forming a mechanical base for the printed circuit board; a first copper layer laminated to a first side of the substrate forming a first conductive metallic paths for the printed circuit board; a first solder mask applied over the first copper layer and the first side of the substrate to seal the first array of conductive metallic paths from an external environment; and a first de-coupling plane printed on the printed circuit board using conductive ink.

Implementations disclosed and claimed herein further include a second copper layer laminated to a second side of the substrate forming a second array of conductive metallic paths for the printed circuit board; a second solder mask applied over the second copper layer and the second side of the substrate to seal the second array of conductive metallic paths from the external environment; and a second de-coupling plane printed over the second solder mask using the conductive ink.

Implementations disclosed and claimed herein further include a second copper layer laminated over the first de-coupling plane forming a second array of conductive metallic paths for the printed circuit board; a second solder mask applied over the second copper layer and the first printed de-coupling plane to seal the second array of conductive metallic paths from the external environment; and a second de-coupling plane printed over the second solder mask using the conductive ink.

In some implementations disclosed herein, the first de-coupling plane is printed over the first solder mask.

In some implementations disclosed herein, first de-coupling plane is printed over a second side of the substrate.

Implementations disclosed and claimed herein further include a second solder mask applied over the first de-coupling plane to seal the first de-coupling plane from the external environment.

In some implementations disclosed herein, the first solder mask is excluded from one or more discrete areas of the first copper layer corresponding to electrical ground, and wherein the first de-coupling plane is connected to electrical ground at the one or more discrete areas.

In some implementations disclosed herein, the conductive ink includes one or more of carbon, copper, and silver powder suspended within a printable solution.

Implementations disclosed and claimed herein further include one or more electronic components soldered to the substrate, wherein the first de-coupling plane serves as one or both of a high-frequency current return path and a common electrical ground for low-frequency current for the one or more electronic components.

In some implementations disclosed herein, the conductive metallic paths include one or more of vias, traces, and pads on the printed circuit board.

Implementations disclosed and claimed herein include a method of manufacturing a printed circuit board, the method comprising: providing a substrate forming a mechanical base for the printed circuit board; laminating a first copper layer to a first side of the substrate forming a first array of conductive metallic paths for the printed circuit board; applying a first solder mask over the first copper layer and the first side of the substrate to seal the first array of conductive metallic paths from an external environment; and printing a first de-coupling plane on the printed circuit board using conductive ink.

Implementations disclosed and claimed herein further include laminating a second copper layer to a second side of the substrate forming a second array of conductive metallic paths for the printed circuit board; applying a second solder mask over the second copper layer and the second side of the substrate to seal the second array of conductive metallic paths from an external environment; and printing a second de-coupling plane on the printed circuit board using the conductive ink.

Implementations disclosed and claimed herein further include laminating a second copper layer over the first de-coupling plane forming a second array of conductive metallic paths for the printed circuit board; applying a second solder mask applied over the second copper layer and the first printed de-coupling plane to seal the second array of conductive metallic paths from the external environment; and printing a second de-coupling plane over the second solder mask using the conductive ink.

In some implementations disclosed herein, the first de-coupling plane is printed over the first solder mask.

In some implementations disclosed herein, the first de-coupling plane is printed over a second side of the substrate.

Implementations disclosed and claimed herein further include applying a second solder mask over the first de-coupling plane to seal the first de-coupling plane from the external environment.

In some implementations disclosed herein, the first solder mask is excluded from one or more discrete areas of the first copper layer corresponding to electrical ground, and wherein the first de-coupling plane is connected to electrical ground at the one or more discrete areas.

In some implementations disclosed herein, the conductive ink includes one or more of carbon, copper, and silver powder suspended within a printable solution.

Implementations disclosed and claimed herein include a printed circuit board comprising: a substrate forming a mechanical base for the printed circuit board; a first copper layer laminated to a first side of the substrate forming a first array of conductive metallic paths for the printed circuit board; a first solder mask applied over the first copper layer and the first side of the substrate to seal the first array of conductive metallic paths from an external environment; a first carbon de-coupling plane printed on the printed circuit board using conductive carbon ink; a second copper layer laminated to a second side of the substrate forming a second array of conductive metallic paths for the printed circuit board; a second solder mask applied over the second copper layer and the second side of the substrate to seal the second array of conductive metallic paths from the external environment; and a second carbon de-coupling plane printed over the second solder mask using the carbon conductive ink.

In some implementations disclosed herein, the conductive ink includes one or more of carbon, copper, and silver powder suspended within a printable solution.

The above specification, examples, and data provide a complete description of the structure and use of exemplary embodiments of the invention. Since many embodiments of the invention can be made without departing from the spirit and scope of the invention, the invention resides in the claims hereinafter appended. Furthermore, structural features of the different embodiments may be combined in yet another embodiment without departing from the recited claims.

What is claimed is:

1. A printed circuit board comprising:
a substrate forming a mechanical base for the printed circuit board;
a first copper layer laminated to a first side of the substrate forming a first conductive metallic paths for the printed circuit board;
a first solder mask applied over the first copper layer and the first side of the substrate to seal the first array of conductive metallic paths from an external environment; and
a first de-coupling plane printed on the printed circuit board using conductive ink.

2. The printed circuit board of claim 1, further comprising:
a second copper layer laminated to a second side of the substrate forming a second array of conductive metallic paths for the printed circuit board;
a second solder mask applied over the second copper layer and the second side of the substrate to seal the second array of conductive metallic paths from the external environment; and
a second de-coupling plane printed over the second solder mask using the conductive ink.

3. The printed circuit board of claim 1, further comprising:
a second copper layer laminated over the first de-coupling plane forming a second array of conductive metallic paths for the printed circuit board;
a second solder mask applied over the second copper layer and the first printed de-coupling plane to seal the second array of conductive metallic paths from the external environment; and
a second de-coupling plane printed over the second solder mask using the conductive ink.

4. The printed circuit board of claim 1, wherein the first de-coupling plane is printed over the first solder mask.

5. The printed circuit board of claim 1, wherein the first de-coupling plane is printed over a second side of the substrate.

6. The printed circuit board of claim 1, further comprising:
a second solder mask applied over the first de-coupling plane to seal the first de-coupling plane from the external environment.

7. The printed circuit board of claim 1, wherein the first solder mask is excluded from one or more discrete areas of the first copper layer corresponding to electrical ground, and wherein the first de-coupling plane is connected to electrical ground at the one or more discrete areas.

8. The printed circuit board of claim 1, wherein the conductive ink includes one or more of carbon, copper, and silver powder suspended within a printable solution.

9. The printed circuit board of claim 1, further comprising:
one or more electronic components soldered to the substrate, wherein the first de-coupling plane serves as one or both of a high-frequency current return path and a common electrical ground for low-frequency current for the one or more electronic components.

10. The printed circuit board of claim 1, wherein the conductive metallic paths include one or more of vias, traces, and pads on the printed circuit board.

11. A method of manufacturing a printed circuit board, the method comprising:
providing a substrate forming a mechanical base for the printed circuit board;
laminating a first copper layer to a first side of the substrate forming a first array of conductive metallic paths for the printed circuit board;
applying a first solder mask over the first copper layer and the first side of the substrate to seal the first array of conductive metallic paths from an external environment; and
printing a first de-coupling plane on the printed circuit board using conductive ink.

12. The method of claim 11, further comprising:
laminating a second copper layer to a second side of the substrate forming a second array of conductive metallic paths for the printed circuit board;
applying a second solder mask over the second copper layer and the second side of the substrate to seal the second array of conductive metallic paths from an external environment; and
printing a second de-coupling plane on the printed circuit board using the conductive ink.

13. The method of claim 11, further comprising:
laminating a second copper layer over the first de-coupling plane forming a second array of conductive metallic paths for the printed circuit board;
applying a second solder mask applied over the second copper layer and the first printed de-coupling plane to seal the second array of conductive metallic paths from the external environment; and
printing a second de-coupling plane over the second solder mask using the conductive ink.

14. The method of claim 11, wherein the first de-coupling plane is printed over the first solder mask.

15. The method of claim 11, wherein the first de-coupling plane is printed over a second side of the substrate.

16. The method of claim 11, further comprising:
applying a second solder mask over the first de-coupling plane to seal the first de-coupling plane from the external environment.

17. The method of claim 11, wherein the first solder mask is excluded from one or more discrete areas of the first copper layer corresponding to electrical ground, and wherein the first de-coupling plane is connected to electrical ground at the one or more discrete areas.

18. The method of claim 11, wherein the conductive ink includes one or more of carbon, copper, and silver powder suspended within a printable solution.

19. A printed circuit board comprising:
a substrate forming a mechanical base for the printed circuit board;
a first copper layer laminated to a first side of the substrate forming a first array of conductive metallic paths for the printed circuit board;
a first solder mask applied over the first copper layer and the first side of the substrate to seal the first array of conductive metallic paths from an external environment;
a first carbon de-coupling plane printed on the printed circuit board using conductive carbon ink;
a second copper layer laminated to a second side of the substrate forming a second array of conductive metallic paths for the printed circuit board;
a second solder mask applied over the second copper layer and the second side of the substrate to seal the second array of conductive metallic paths from the external environment; and
a second carbon de-coupling plane printed over the second solder mask using the conductive carbon ink.

20. The printed circuit board of claim 19, wherein the conductive carbon ink includes carbon powder suspended within a printable solution.
